(19) United States
(12) Patent Application Publication
(10) Pub. No.: US 2022/0372629 A1
(43) Pub. Date: Nov. 24, 2022

(54) SUBSTRATE WITH A MOLYBDENUM NITRIDE LAYER SYSTEM, AND COATING METHOD FOR PRODUCING A LAYER SYSTEM

(71) Applicant: OERLIKON SURFACE SOLUTIONS AG, PFÄFFIKON, Pfäffikon (CH)

(72) Inventors: Jörg VETTER, Bergisch Gladbach (DE); Jürgen BECKER, Geisenheim (DE); Johann KARNER, Triesen (LI)

(73) Assignee: OERLIKON SURFACE SOLUTIONS AG, PFÄFFIKON, Pfäffikon (CH)

(21) Appl. No.: 17/761,777

(22) PCT Filed: Sep. 17, 2020
(86) PCT No.: PCT/EP2020/075978

§ 371 Date: Mar. 18, 2022

(30) Foreign Application Priority Data
Sep. 19, 2019 (EP) 19198389.9

(51) Int. Cl. C23C 28/04; C23C 14/06; C23C 28/00

(52) U.S. Cl. CPC C23C 28/046; C23C 14/0641; C23C 28/044; C23C 28/343; C23C 14/0605; C23C 28/36; C23C 28/048

(57) ABSTRACT

A substrate having a multilayer coating system in the form of a surface coating, which has an outer cover layer comprising amorphous carbon, and a coating process for producing a substrate. At least a first MoₐNₓ support layer is provided between the substrate and the cover layer, which support layer has a nitrogen content x, referred to an Mo content a, which is in the range of 25 at %≤x≤55 at %, with x+a=100 at %.

The invention relates to a substrate having a multilayer coating system in the form of a surface coating, in particular on a surface of a wear part, such as a tool or a machine part, as well as to a process for producing a surface coating according to the preamble of the independent claim of the respective category.

The production of high-performance tools or all kinds of components exposed to wear is mostly realized by coating their surfaces. An important class of such coated substrates are, inter alia, tools or parts of machines, e.g., of internal combustion engines, or in particular also tools for forming, machining tools as well as other components, in particular wear parts for machines in all possible designs.

In practice, typical substrate materials that are coated are, inter alia, steels of all kinds, tool steels or hard metals, but also all kinds of other substrate materials, such as ceramics in particular. Steels with low tempering temperatures, around 200° C., such as ball bearing steels, are also particularly in line to increase their performance for components such as engine components. In particular, friction reduction and compatibility with lubricants as well as sufficient resistance at the operating temperature play a role.

In the state of the art, there are a whole range of different surface coatings, which are known to the person skilled in the art, with which the performance of substrates subject to high stress at the surface can be significantly improved. For example, different nitride coatings, e.g. CrN, or oxynitride coatings such as CrNO, or carbonitride coatings such as TiCN, as well as various DLC coatings are applied.

For example, ceramic cutting bodies, for example based on cubic boron nitride, are preferably used for hard machining of steels in particular. Thus, inter alia, a wide variety of SiN ceramics are increasingly used for high-speed machining of Al alloys and gray cast iron. The ceramics prove to be much more resistant compared to the metallic tool materials, wherein suitable coatings can additionally be provided on the ceramic tools to further enhance performance.

However, more widespread in industrial technology is the coating of metallic substrate bodies, in particular substrate bodies made of steels of all kinds. The hard coatings known from the state of the art are often based on classic compounds such as TiN, TiNC, or CrN. However, these known hard coatings have their limits in terms of their range of application due to their special physical properties, not only, but in particular, in terms of temperature resistance. On the one hand, the hardness decreases noticeably at elevated temperatures, and on the other hand, an oxidation already starts at relatively low temperatures, which can lead to increased coating wear at the operating temperature.

In order to avoid these problems, two classes of coatings have been substantially developed in the state of the art which have an oxidation resistance in the range of up to 1000° C. and also have improved properties in terms of hardness.

One layer class concerns Al-containing base layers such as AlTiN and AlCrN, whereby, depending on the requirement, additional elements can be alloyed in. Typical compounds from this area are compounds of the form of AlTiXNCO, wherein X is e.g. Cr or another metal.

Another approach taken in the state of the art to improve the performance of coated tools is the combination of classic hard coatings as a carrier layer combined with finish coatings as a functional layer. In particular, the high-Si coatings (10 at % or more; in the context of this application, at % means “atomic percent”) of the MeSiXNCO coating type (X other metals or B) such as TiSiN, which enable a significantly improved temperature load are to be mentioned here as finish coatings.

In addition, it is also known, for example, to deposit oxide ceramic layers such as Al₂O₃ on indexable inserts by means of CVD processes in order to counter wear processes at elevated contact temperatures, in particular during turning.

In addition, it is also known to use boron-based coatings, such as B₄C or even cubic BN coatings. However, cubic BN has the significant disadvantage that it is extremely complicated to image. This is mainly due to difficulties in the layer growth itself, but also due to the high residual stresses in the layers.

In the field of high-temperature materials, volume ceramics based on SiCN have been produced in recent years, which are characterized by high hardness and an improvement in oxidation resistance compared to SiC and Si₃N₄. Their special properties are due to the complex covalent chemical bonds and the low diffusion rate of oxygen in the amorphous structure of SiCN.

Corresponding diverse state of the art can be found e.g. in the writings WO 2017/148 582 A1, EP 3 074 550 B1, WO 2017/174 197 A1, WO 2016/188 632 A1, which refer to pure MoN coatings.

However, in spite of all previous efforts, only partial success has been achieved in providing coatings that meet the ever-increasing requirements for mechanical properties, such as hardness, compressive residual stresses and toughness, tribological properties such as adhesion tendency at higher temperatures as well as friction, the oxidation resistance, phase stability and other characteristic properties, in particular at defined operating temperatures.

In recent years, coating systems have also become increasingly established, which often consist of one or more layers of amorphous (diamond-like) carbon coatings (DLC coatings) except for adhesive layers.

However, there are also significant limitations with regard to the application of this type of coating. The coatings, in particular the DLC coatings with hardnesses of more than 30 GPa, often have strong compressive residual stresses, so that the reasonably applicable coating thickness is significantly limited. Mechanical stress is also limited, in particular on soft substrates, which have much lower hardnesses and Young's moduli than the corresponding coating. Furthermore, the functionality is only limited to the layer volume of the DLC layers. In the case of local wear, after some time the mostly metallic adhesive layer (e.g. Cr) is reached by (local) removal of the DLC layers, which usually has poor tribological properties.

It is therefore an object of the invention to provide an improved surface coating for a substrate, in particular for a wear part, such as a tool or a machine part or any other wear part subject to mechanical, tribological or thermal stresses, which overcomes the problems known from the state of the art and, in particular, has tribologically positive behavior, improved mechanical properties, above all, but not only, in terms of hardness and compressive residual stresses, and can also be used at increased temperatures.

A further object of the invention is to provide a process for the production of such an improved coating, in particular which is suitable for coating in the temperature range from 100 to 300° C., especially about 150-200° or around 200° C.

The subject matters of the invention meeting this object are characterized by the features of the respective independent claims.

The dependent claims relate to particularly advantageous embodiments of the invention.

Thus, the invention relates to a coating process for producing a coating system on a substrate, and to a substrate having a multilayer coating system in the form of a surface coating, which has an outer cover layer comprising amorphous carbon. According to the invention, at least a first MoₐNₓ support layer is provided between the substrate and the cover layer, which support layer has a nitrogen content x, referred to an Mo content a, which is in the range of 25 at %≤x≤55 at %, with x+a=100 at %.

The substrate coated according to the invention can be in particular a component of a component subject to wear and/or friction, especially a component of a motor vehicle or of an internal combustion engine, in particular a piston, or a piston ring, a valve, a valve disk, or another component of an internal combustion engine or a tool, such as a cutting tool, a forming tool, a machining tool, or another tool subject to wear and/or friction or any other component that is subject to wear.

It has been shown by the present invention that the problems described above can be avoided to a very large extent with DLC coating systems known from the state of the art, and that a coating system according to the invention is used to particular advantage in the aforementioned parts and components in particular. The use of MoN support layers according to the present invention overcomes the above-mentioned disadvantages, in particular also for the extremely hard tetrahedral amorphous carbon layers (ta-C layers), which are mostly in the hardness range above 30 GPa and have Young's moduli, measured with the nanohardness, of more than 300 GPa.

The coating system according to the invention comprising at least one MoₐNₓ support layer and a hard amorphous carbon layer or diamond-like carbon layer, which for the sake of simplicity are also referred to synonymously as DLC layer in the context of this application, e.g. a hydrogen-free a-C cover layer or a ta-C cover layer or another type of layer made of amorphous carbon as an outwardly closing cover layer, serves primarily, but not exclusively, to reduce wear and friction in connection with lubricants on components such as automotive components, in tools or other heavily loaded components or wear parts of any kind. As will be explained in more detail below, the deposition is particularly preferably carried out by means of processes known in principle per se, such as by means of a PVD process, CVD process, PA-CVD process, sputtering process, preferably HIPMS sputtering process, in particular a filtered or unfiltered arc coating process, or by means of a combination or hybrid process comprising one or more of the aforementioned coating processes.

Substantial features of this layer structure compared to the state of the art are, above all, the improved support effect, which enables an increased total layer thickness and higher point loads are possible. In addition, in the case of a coating system according to the invention, a significantly improved functionality in the event of coating wear or flaking due to the formation of Magneli phases caused by oxidation at sufficient operating temperatures is enabled.

As the person skilled in the art knows, molybdenum can form a variety of compounds or modifications, also called phases, with nitrogen, which can have different crystal structures and properties. At low nitrogen contents, for example, phase mixtures of metallic molybdenum Mo plus Mo₂N phases can be generated. With increase of the nitrogen content, Mo₂N phases are generated, and with even further increase of nitrogen, phase mixtures of Mo₂N plus MoN can be generated. Finally, MoN is generated. However, superstoichiometric MoN with (N/Mo>1) has also been reported.

For the improvement of tribological properties by a functional layer of the molybdenum nitride MoNₓ type, layers with the following phases or phase mixtures have been analyzed: layers with exclusively or mainly γ-Mo₂N, or a molybdenum nitride layer with exclusively or mainly δ-MoN, or a molybdenum nitride layer with both γ-Mo₂N and δ-MoN. In WO 2015/096882 A3, the applicant of the present invention has already reported that a MoN-based hard coating comprising at least mostly the hexagonal phase of the molybdenum nitride δ-MoN, wherein the intensity ratio of the two peaks (δ-MoN 220)/(δ-MoN 200) is >3, preferably >10, particularly preferably >30, is most suitable.

In the case of pure Mo₂N layers, the minimum nitrogen content is approx. 27 at % referred to at % (Mo)+at % (N)=100 at %. The maximum nitrogen content of the MoN layers is up to 55 at %, depending on the phase composition.

The layers always have MoNₓ phases except for a minority proportion of metallic molybdenum. The layers can consist of pure Mo₂N phases, or be Mo₂N/MoN phase mixtures, or even consist of pure MoN. The MoN sublayers can be multilayered in terms of composition.

The first MoₐNₓ support layers according to the invention and the second Mo_{b}N_{y} support layers described in more detail below can be deposited in separate processes under the outwardly closing DLC cover layer. As an alternative, the layer according to the invention can also be deposited in one process.

For example, a δ-MoN (delta-molybdenum nitride) can also be used for tribological applications in a layer system according to the invention under the cover layer of amorphous carbon. However, other MoN phases can also be advantageously suitable. The MoN support layers can also be multilayer systems made of MoN in combination with other nitrides such as CrN, Cr₂N or TiN. Furthermore, doping of the MoN support layers with elements such as copper, oxygen or carbon is possible. (The generalized term MoN support layers means in the context of this application: MoN of whatever nitrogen content and/or phase composition). However, metallic elements such as Al or other elements such as B and Si can also be used for modification. A preferred embodiment of a coating system according to the invention is the use of a support layer which comprises at least for the most part the hexagonal phase of the molybdenum nitride δ-MoN and/or consists of pure molybdenum nitride δ-MoN.

Particularly in the case of comparatively soft substrates. e.g., in the case of soft steels, it may be appropriate to additionally deposit an intermediate layer under a MoN support layer in the direction towards the substrates. For example, this can be a CrNₓ layer. It can also often be useful to deposit a metallic adhesive layer on the substrates, such as a Cr adhesive layer.

In a particular embodiment of a coating system according to the invention, the nitrogen content x of the first MoₐNₓ support layer is in the range of 30 at %≤x≤53 at % and is particularly advantageously at about 50 at %.

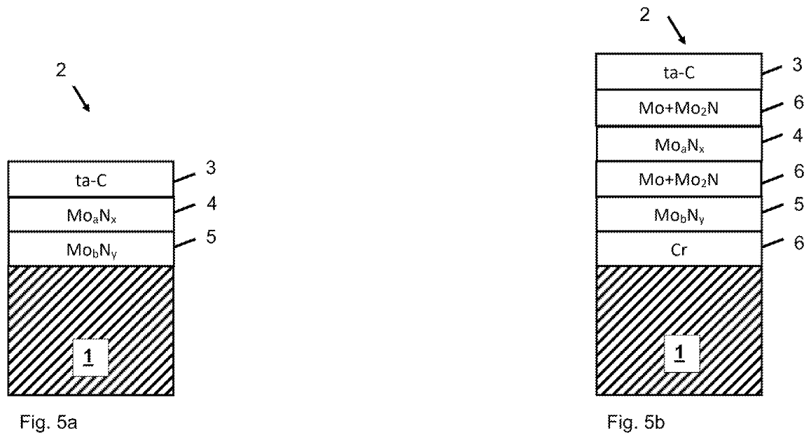

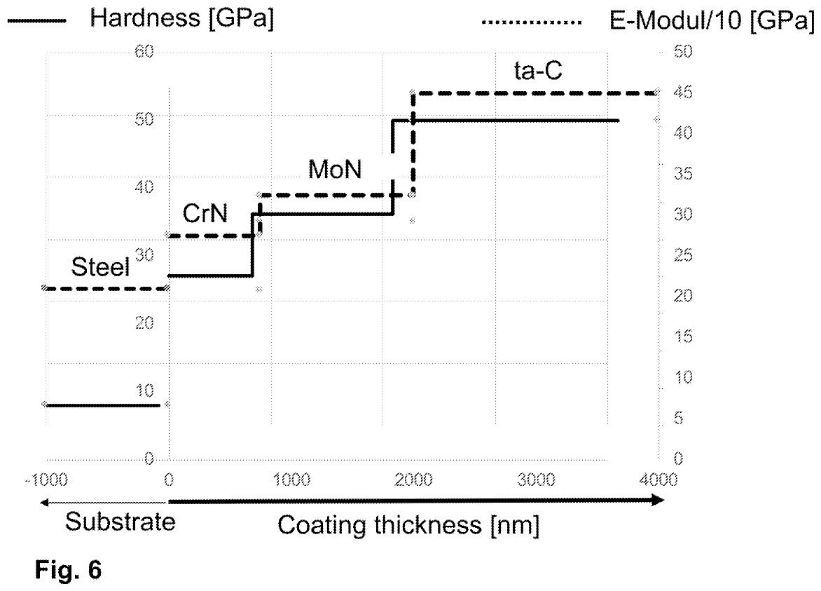

As already mentioned, a coating system of the present invention can comprise at least a second Mo_{b}N_{y} support layer between the substrate and the first MoₐNₓ support layer and/or between the first MoₐNₓ support layer and the outer cover layer, wherein, referred to a Mo content b of the second Mo_{b}N_{y} support layer, a nitrogen content y is in the range of 35 at %≤y≤45 at %, with y+b=100 at %, preferably at 40 at %. Particularly preferably, the hardness of the first MoₐNₓ support layer, which is arranged closer to the cover layer of the system, is greater than the hardness of the second support layer, which is arranged closer to the substrate, as will be explained in more detail below with reference to the specific embodiments according to FIG. 5a and FIG. 5b or by FIG. 6.

It is understood that a plurality of respectively identical or different first MoₐNₓ support layers can also be provided between the substrate and the outer cover layer of amorphous carbon and/or that a plurality of respectively identical or different second Mo_{b}N_{y} support layers can also be provided between the substrate and the outer cover layer of amorphous carbon.

Depending on the substrate and/or application, e.g., depending on whether the substrate is a tool, such as a cutting tool, or a machine component, such as a component for an internal combustion engine, the first MoₐNₓ support layer and/or the second Mo_{b}N_{y} support layer can contain a proportion of metallic Mo. Particularly preferred, a phase mixture of Mo and Mo₂N in the first MoNₓ and in the second Mo_{b}N_{y} support layer is adjusted by adjusting a nitrogen content x and y, respectively, between 5 at % and 20 at %, in each case under the boundary condition x+a=100 at % and y+b=100 at %.

In the case of another embodiment, the first MoₐNₓ support layer and/or the second Mo_{b}N_{y} support layer can also be composed of pure Mo₂N phases and their phase mixtures β-Mo₂N and γ-Mo₂N, and/or also of Mo₂N/MoN phase mixtures and/or of pure MoN phases, in particular of cubic MoN and/or hexagonal δ-MoN phases or phase mixtures. In this context, the γ-Mo₂N as well as the pure hexagonal phase of the δ-MoN are particularly preferred.

In a further embodiment of the present invention, the first MoₐNₓ support layer and/or the second Mo_{b}N_{y} support layer can also additionally comprise one or more elements of the group consisting of [Ag, Cr, Ti, Cu, Al, Si, B, O, C] and/or also an element of the 4th, 5th or 6th group of the periodic table of the elements. The first MoₐNₓ support layer and/or the second Mo_{b}N_{y} support layer can advantageously also comprise at least one layer of the composition (MoₓM_{z})_{c}(NᵤCᵥO_{w})_{d}, acting as a support layer, wherein an M comprises at least one of the elements of the 4th to 6th group of the periodic table, and/or one of the elements Si, B, Al, Cu, Ag, with x+z+u+v+w=100 at %, and c/d=3, wherein 25 at %≤x≤55 at % and 0≤z≤20 at %, 0≤v≤5 at % and 0≤w≤5 at %.

For the improvement of the adhesion on the surface of the substrate or for the improvement of the adhesion between the various layers of a coating system according to the invention, an adhesive layer can additionally be provided on a surface of the substrate and/or on a surface of the first MoₐNₓ support layer and/or on a surface of the second Mo_{b}N_{y} support layer and/or on a surface of an intermediate layer, which adhesive layer is alloyed in particular with one or more elements from the group consisting of [C, N, O]. Furthermore, the adhesive layer can also advantageously comprise, except for impurities, one or more elements of the 4th, 5th or 6th group of the periodic table of the elements, in particular also comprising one of the elements Cr, Ti, Cu, Al, or Mo.

As already mentioned in the discussion of the adhesive layers, a coating system according to the invention can also additionally comprise one or more intermediate layers beneath the support layer. In particular, the intermediate layer may comprise, for example, single-phase metal nitrides, metal carbides as well as metal carbonitrides and/or phase mixtures of metal nitrides, metal carbides and metal carbonitrides, wherein the intermediate layer comprises in particular a single-phase Cr₂N or CrN layer or a phase mixture of CrN and Cr₂N.

In particular, the first MoₐNₓ support layer and/or the second Mo_{b}N_{y} support layer and/or the intermediate layer and/or the adhesive layer can be designed in the form of a gradient layer with respect to the chemical composition or with respect to another physical or chemical property, wherein, in particular, an adjustment between two different layer types in the coating system can be optimally made by the gradient layer.

A thickness d of the first MoₐNₓ support layer and/or of the second Mo_{b}N_{y} support layer and/or of the intermediate layer can be in the range of 0.05 μm≤d≤50 μm, preferably in the range of 0.03 μm≤d≤30 μm, especially in the range of 0.2 μm≤d≤25 μm, or in the range of 0.3 μm≤d≤10 μm.

Due to the integration of further additional layers between the substrate and the cover layer, as described above, such as due to one or more first MoₐNₓ or second Mo_{b}N_{y} support layers and/or due to one or more adhesive layers and/or intermediate layers, inter alia, layer properties such as the stability, hardness, above all also the temperature resistance, the adaptation to impact loads or also the ductility, etc. can be individually adapted or further improved in a coating system according to the invention depending on the application and substrate.

The compositions of the individual layers of the coating system under the cover layer, or the adjusting of the special MoN phases and phase mixtures mentioned, can be adjusted in practice, for example, as follows. In dependence on the coating process selected in the particular case, e.g., whether it is a PVD process, a CVD process, a high-energy pulsed magnetron sputtering (HIPIMS), an arc evaporation process or another suitable coating process, the nitrogen partial pressure, the bias voltage on the substrate, or e.g. the substrate temperature or another relevant parameter can be adjusted in the coating chamber in a suitable manner known to the person skilled in the art or varied according to a predeterminable scheme during the coating process in order to achieve a specific coating composition. Depending on the coating process, other process parameters can also be important, such as, for example, in the case of an arc evaporation process (arc process), the influence of the evaporator, the magnetic field, the evaporation current and other parameters known per se to the person skilled in the art, which, by suitable adjustments, lead to the desired coating composition or the desired coating structure. As a rough guideline, it can be assumed in special cases, for example, that the formation of phase mixtures of Mo+Mo₂N in the layers tends to be favored at nitrogen partial pressures up to approx. 0.4 Pa and/or higher substrate bias voltages up to e.g., 250V and more. In the case of nitrogen partial pressures up to, e.g., about 1 Pa, the formation of Mo₂N phases tends to be favored, while in the case of even higher nitrogen partial pressures from about 2 Pa up to above 2 Pa and substrate bias voltages up to about 150V, Mo₂N+MoN phases are preferably formed.

These and other aforementioned phases and phase mixtures in the deposited coating systems can be detected in a manner known per se, for example by means of X-ray diffraction and other methods known per se, and the elemental compositions can be detected by corresponding methods such as EDX, WDX, SIMS or other measurement and analysis methods which are well known to the person skilled in the art.

Now that the basic properties and embodiments of the coating system according to the invention in the region between the cover layer of amorphous carbon and the substrate have been explained in overview form, the basic properties and possible preferred embodiments of cover layers of amorphous carbon, as provided in a coating system of the invention, will be explained in the following.

The outer cover layer comprising the amorphous carbon of a coating system according to the invention is an amorphous carbon layer of the a-C type known per se, an amorphous carbon layer of the a-C:X type doped with an element X, a tetrahedral amorphous carbon layer of the ta-C:X type doped with an element X, an amorphous carbon layer of the a-C:Me type doped with a metal, a tetrahedral amorphous carbon layer of the ta-C:Me type doped with a metal, an amorphous carbon layer of the a-C:H:Me type doped with a metal and hydrogen, or a tetrahedral amorphous carbon layer of the ta-C:H:Me type doped with a metal and hydrogen. Of course, the cover layer can comprise in particular one or more of the aforementioned types of amorphous carbon layers. Here, X is preferably an element from the group of elements consisting of [F, Cl, B, N, O, Si] and Me is one or more elements from the 4th, 5th or 6th group of the periodic table of the elements, and Me can further also comprise Al or Cu, preferably one of the elements Mo, Cr, Ti, W, Al.

In a particular embodiment, the cover layer of a coating system according to the invention can comprise two or more layers each comprising an amorphous carbon layer of the a-C type, or of the a-C:X type, or of the ta-C:X type, or of the a-C:Me type, or of the ta-C:Me type, or of the a-C:H:Me type, or of the ta-C:H:Me type.

Of course, it is also possible that the cover layer and/or a layer of the of the cover layer comprises a gradient layer which is an amorphous carbon layer of the a-C type, or of the a-C:X type, or of the ta-C:X type, or of the a-C:ME type, or of the ta-C:Me type, or of the a-C:H:Me type, or of the ta-C:H:Me type.

For example, depending on the requirements, two different layers can have a different sp³/sp² ratio, wherein, as is known to the person skilled in the art, sp³ and sp² are bonding states of the carbon atoms, or in a gradient layer, a sp³/sp² ratio can vary over a thickness of the gradient layer, so that under the gradient layer between two adjacent partial layers, certain layer properties such as the stability, hardness, above all also the temperature resistance etc. can be individually adapted depending on the application, substrate or other special boundary conditions.

In practice, a thickness Dd of the cover layer and/or of a layer of the cover layer is advantageously in the range of 0.05 μm≤Dd≤50 μm, preferably in the range of 0.05 μm≤Dd≤30 μm, especially in the range of 0.1 μm≤Dd≤20 μm, or in the range of 0.5 μm≤Dd≤10 μm, preferably in the range of 1 μm≤Dd≤5 μm, particularly preferably the thickness Dd is at about 2 μm.

A total thickness Gd of a coating system of the present invention is selected in a range of 0.1 μm≤Gd≤100 μm, preferably in the range of 0.5 μm≤Gd≤50 μm, especially in the range of 1 μm≤Gd≤10 μm, particularly preferably at about 4 μm, wherein a ratio of the thickness Dd of the cover layer to the total thickness of the Gd of the entire coating system is in the range of 1%≤(Dd/Gd)≤1000%, preferably in the range of 10%≤(Dd/Gd)≤500%, especially in the range of 20%≤(Dd/Gd)≤200% and particularly preferably in the range of 40%≤(Dd/Gd)≤120%.

A hardness Hd of the cover layer is in a range of 8 GPa≤Hd≤80 GPa, especially in the range of 10 GPa≤Hd≤70 GPa, or in the range of 25 GPa≤Hd≤60 GPa and is particularly preferably about 50 GPa. A ratio of the hardness Hd of the cover layer to the hardness Hs of the entire support layer is in a range between (Hd/Hs)==1:5 to (Hd/Hs)=4:1, preferably in the range between (Hd/Hs)=1:2 to (Hd/Hs)=3:1, and is in particular in the range of (Hd/Hs)=1:1.5 to (Hd/Hs)=2:1. The hardness can be determined by nano-penetration, in particular according to ISO 14577.

In the following, for a better understanding of the invention, some particularly advantageous embodiments of coating systems will be briefly described, mentioning specific coating parameters, before further special embodiments will be discussed on the basis of the drawing.

In a particular embodiment of a coating system according to the invention, for example, a chromium-based substructure may be provided as an adhesive layer on the substrate, wherein the adhesive layer consists essentially of chromium, for example, with a thickness of the chromium layer of about 0.1 μm. A CrN intermediate layer, preferably in the form of a Cr₂N+CrN phase mixture with a thickness of 0.5 μm follows the chromium adhesive layer. A support layer of δ-MoN with a thickness of approx. 2 μm is further provided on the intermediate layer. Finally, a cover layer of amorphous carbon of the ta-C type, with a hardness of approx. 50 GPa and a thickness of approx. 1 μm, forms the outer layer. For example, the entire coating system can be deposited on the substrate using an arc (ARC) coating process known per se.

In another embodiment of the coating system according to the invention described above, it is also possible, for example, to deposit multilayer coatings of CrN/MoN, wherein the partial layer directly adjacent to the cover layer of amorphous carbon is particularly advantageously a MoN layer in the sense defined above.

As already mentioned, particularly advantageous is a cover layer of amorphous carbon of the a-C, ta-C, a-C:X, ta-C:X, a-C:Me, a-C:H, a-C:H:X, a-C:H:Me type and had a layer thickness in the range of at least 100 nm to 20 μm. The cover layer can be a single-layer monolayer, a multilayer coating or also a gradient layer. As already explicitly mentioned and listed several times, different types of cover layers of amorphous carbon can also be combined in one and the same cover layer. The multilayer cover layer or the cover layer in the form of a gradient layer can be realized by changing the sp³/sp² content of C—C bonds by changing process parameters or even by the combination of different types e.g. ta-C with ta-C:N.

In practice, the layer of the coating system that is arranged immediately adjacent to the cover layer of amorphous carbon is in most cases a MoN layer. This means, preferably a first MoₐNₓ support layer or a second Mo_{b}N_{y} support layer. The cover layer of amorphous carbon is then deposited directly on the MoN layer with suitable parameters. However, in certain cases, it can be advisable to deposit a metallic adhesive layer between the MoN layers and the cover layers of amorphous carbon, e.g., metallic Mo or Cr, as will be described later on the basis of further embodiments in the drawings.

The MoN under the cover layer of amorphous carbon has a particularly positive effect if they have a high hardness and a high Young's modulus. The positive effect becomes particularly evident with hardnesses of ta-C layers, i.e., layers with Young's moduli above 300 GPa.

In addition to a-C and ta-C layers, a-C:Me layers can also be provided particularly advantageously as a cover layer for a coating system according to the invention. These layers contain at least one metal as a doping element and have changed property profiles compared to the a-C and ta-C layers without doping element, for example, the electrical conductivity is greater. Thus, this can be advantageous in certain applications. Since the sublayer contains at least Mo or also Cr, it can be advantageous from a process point of view to use Mo and/or Cr as Me.

A particularly simple process control for the production of a coating system according to the invention is obtained when Mo and/or Cr evaporation is also carried out at the same time as carbon evaporation by means of arc. A further method is the use of carbon targets in which metallic components are admixed.

According to a further embodiment of the present invention, the hydrogen-free amorphous layer is an a-C:X layer, wherein X is preferably an element from the group of elements consisting of [F, Cl, B, N, O, Si].

In addition to metallic elements which are added to the layers and thus lead to the a-C:Me layers, other non-metallic elements can thus also be added as doping elements for the optimization of the layers depending on the application. These non-metallic elements can be boron, silicon, fluorine, or others. For example, Si leads to stress reduction and F to a change in wetting properties, in particular to a larger contact angle.

According to a further preferred embodiment of the present invention, the hydrogen-free amorphous layer is designed as a multilayer coating, wherein the multilayer coating structure comprises alternately arranged single layers of a type A and a type B, wherein the single layers of type A consist of a-C or ta-C and the single layers of type B are of Me or of a-C:Me. For example, in this context, Mo can be used as Me, so that a multilayer coating of the type a-C/Mo or a-C/a-C:Mo, or even ta-C/Mo or ta-C/a-C:Mo or ta-C/ta-C:Mo or a-C/ta-C:Mo is formed.

In doing so, thicker layers can be produced because the overall residual stresses in the layers are reduced. This leads to a higher resilience and wear resistance.

According to a further preferred embodiment of the present invention, the hydrogen-free amorphous layer is designed as a multilayer coating, wherein the multilayer coating structure comprises alternately arranged single layers of a type A and a type B, wherein the single layers of type A are composed of a-C or ta-C and the single layers of type B are of a-C:X. In this context, silicon can be used as X, for example. In this case, the silicon addition additionally contributes to the stress minimization of the layers by forming the a-C:Si structure. For the deposition of such layers, additional arc evaporators can be used, which evaporate the graphite cathodes alloyed with the X element, or other suitable PVD processes can be used, e.g. sputtering sources can be used to sputter off the X element.

Preferably, the thickness of the single layers of type A is not more than 1000 nm and not less than 10 nm. Preferably, the thickness of the single layers of type B is also not more than 1000 nm and not less than 10 nm.

In the case of this embodiment, the possibility is also particularly advantageous to combine greater coating thicknesses with a simultaneously optimized stress ratio within the same coating.

The invention further relates to a coating process for producing a coating system of the invention on a substrate, wherein the coating process is a PVD process, a CVD process, a PA-CVD process, a sputtering process, preferably a HIPMS sputtering process, in particular a filtered or unfiltered arc coating process, or a combination or hybrid process comprising at least one of the aforementioned coating processes.

In a particular embodiment of a process according to the invention, the coating of the entire layer system can be deposited on the substrate by means of the unfiltered or filtered arc evaporator.

Particularly advantageously, the substrate can be treated for cleaning the substrate surface and/or a surface of the first MoₐNₓ support layer and/or a surface of the second Mo_{b}N_{y} support layer and/or the intermediate layer and/or the adhesive layer prior to coating by means of argon ions and/or hydrogen with an ion cleaning using an AEGD (Arc Enhanced Glow Discharge) technology, wherein in a subsequent step, an ion treatment can preferably additionally be carried out, for example with Cr ions or Mo ions.

In a preferred embodiment, the deposition of the first MoₐNₓ support layer and/or the second Mo_{b}N_{y} support layer and the cover layer of amorphous carbon is carried out in a PVD system by means of a coating process according to the invention as follows.

For example, a temperature-sensitive steel is selected as substrate, which only allows coating temperatures up to 200° C. (e.g. ball bearing steel 100 Cr6). A PVD machine is used, which has arc evaporators.

A coating plant for carrying out the coating process according to the invention comprises various coating sources (e.g., arc evaporators) in a coating chamber, as well as, inter alia, an AEGD source, heaters and pumps in a manner known per se. Such a coating plant is usually designed in an octagonal structure with two doors. Circular evaporators are used as arc evaporators, wherein several are arranged in a row one above the other. In practice, the system has at least 3 flanges to receive the arc sources. At least one row is equipped with Cr targets, Mo targets and C targets. Here, the turbopumps are installed on the chamber side. A sufficient heating capacity is installed. Likewise, an AEGD device consisting of the necessary components is installed.

After filling the coating chamber with substrates to be coated and placing them on suitable substrate holders, as well as pumping the coating chamber down to high vacuum, the process steps described below are carried out.

In a first step, the substrate is heated to e.g., 150° C. by means of integrated radiant heaters in the coating plant under high vacuum. For an optimum heat distribution on the surface, the substrate is rotated in different degrees of freedom, single, double, or triple rotation

Preferably, an ion cleaning is done in two steps. First, the substrates are etched with argon ions plus hydrogen. This is done by using the well-known AEGD technology and by applying a negative bias voltage to the substrates. In doing so, a cleaning of the substrate surface is achieved.

In a second step, a chromium MIE (chromium metal ion etching), is done which is well-known to the person skilled in the art. For this purpose, the chromium targets are ignited. Due to a negative BIAS voltage of at least −600 V at the substrate, the chromium ions (Cr+) are strongly accelerated from the targets to the substrate. Due to the impact, on the one hand they remove the oxide layer and on the other hand they penetrate the substrate material. This increases the adhesion of the subsequent layers.

A bias voltage of at least 10 V is applied to the substrates to produce the layers between the substrate and the cover layer of amorphous carbon. First, a Cr layer is deposited with a layer thickness of approx. 10 nm to 200 nm using the Cr evaporators. Subsequently, nitrogen is admitted into the system to deposit a CrN layer with a coating thickness of approx. 50 nm to 500 nm. Then, the Mo evaporators are ignited, and the Cr evaporators are switched off. A MoN coating is formed. The process parameters are selected such that the coating temperature is a maximum of 200° C. The coating thickness is selected between 500 nm and 5000 nm.

In order to finally deposit a cover layer of amorphous carbon, the Mo evaporators are first switched off and the nitrogen supply is interrupted. A sufficiently high voltage of at least −200V is applied to the substrates to bombard the previously deposited MoN layer with C ions. Then, the voltage is gradually lowered to deposit the ta-C layer. For hard coatings, voltages in the range of 10 to 100 V are applied and coating temperatures of 100° C. to 200° C. are selected.

In another embodiment, a delta-MoN coating of the hardness 33 GPa and a Young's modulus of 320 GPa was deposited at a total coating thickness of 2.2 μm on a substrate of temperature-sensitive ball bearing steel with a hardness of about 63 HRC in a first coating plant. The layer structure consisted of a Cr adhesive layer with a layer thickness of 100 nm followed by a 200 nm thick CrN layer and a 1.9 μm thick δ-MoN layer. In a second coating plant, a ta-C with a coating thickness of 1.2 μm and a hardness of 55 GPa and a Young's modulus of 370 GPa was then deposited. The typical cracks around the HRC indentation of the parts of the coating system under the cover layer showed up in an HCR indentation of 150 Kp test.

Surprisingly, it is shown that the ta-C, although it has an extremely high hardness, it still has an excellent adhesion around and within the indentation, while at the same time showing that the number or length of cracks in the MoN sublayer were reduced. This shows that the composite has excellent mechanical loadings. With an additional Cr intermediate layer, these results become even better. Then, there are practically no cracks in the part of the coating system under the cover layer of amorphous carbon. This can be advantageous in certain applications.

Further preferred embodiments of the invention are indicated in the drawing. There are shown:

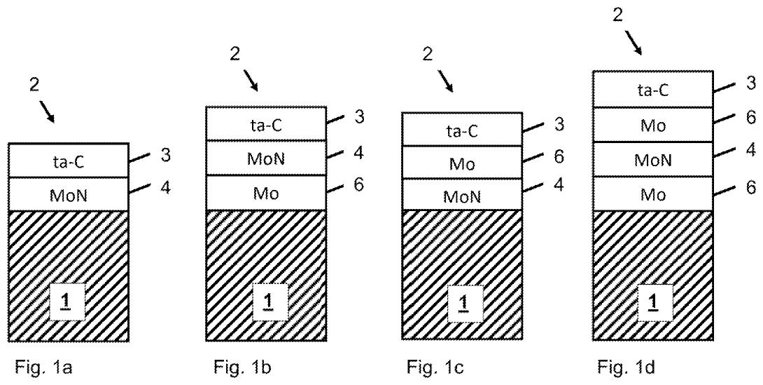

FIG. 1a-1d: First embodiments of layer architectures according to the invention, which comprise only molybdenum or molybdenum support layers between the cover layer of amorphous carbon and the substrate.

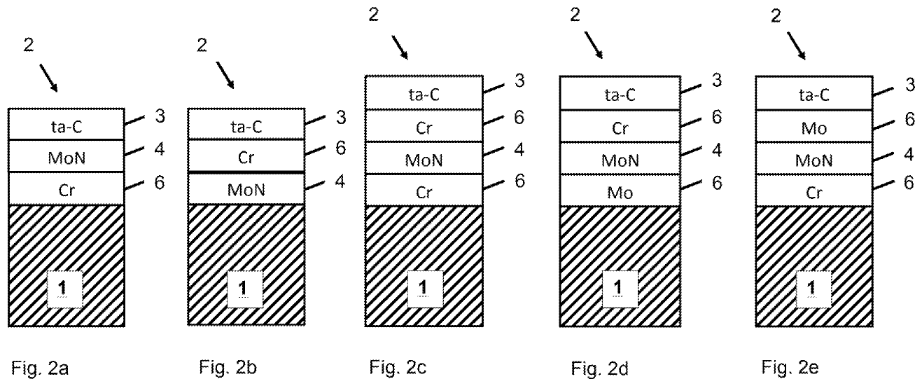

FIG. 2a-2e: A second conception of a layer architecture according to the invention, wherein at least one adhesive layer of a material other than molybdenum is additionally provided between the cover layer of amorphous carbon and the substrate.

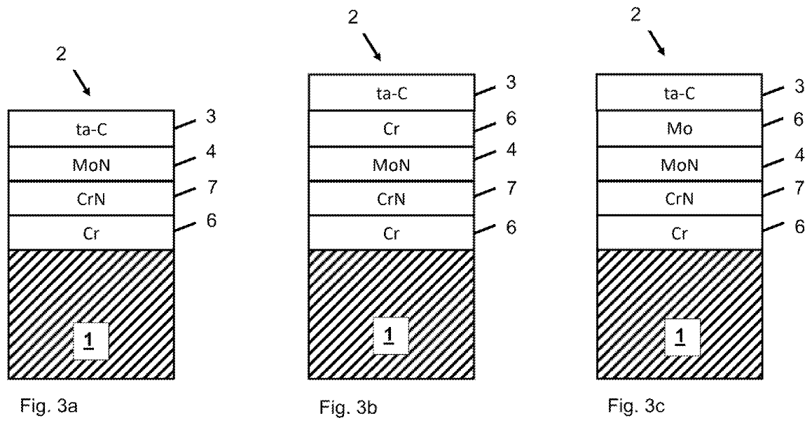

FIG. 3a-3c: Further developments according to the invention of coating systems with additional CrN intermediate layers.

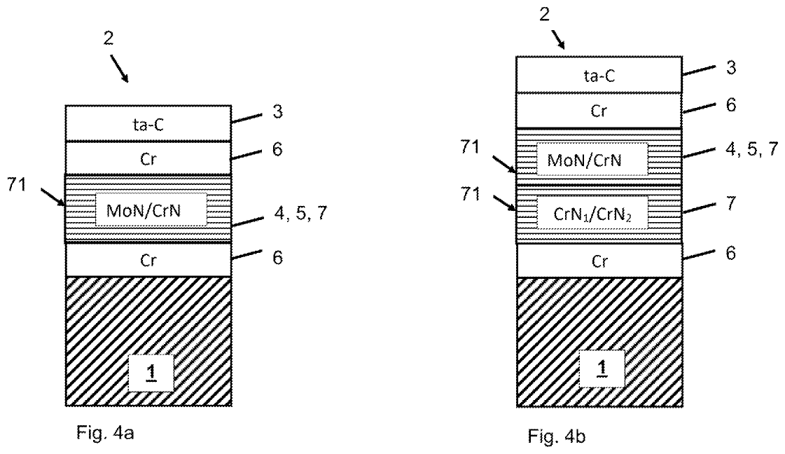

FIG. 4a-4b: Coating systems according to the invention with multilayer coatings.

FIG. 5a-5b: Two further embodiments having at least a first and a second support layer.

FIG. 6: The course of hardness and Young's modulus for a special coating system of the invention as an example.

FIG. 1a to FIG. 1d exemplarily show some preferred embodiments of the present invention with simple layer structures, which comprise only molybdenum Mo or molybdenum support layers MoN between the cover layer of amorphous carbon and the substrate. Such layers are very simple, relatively fast and thus also inexpensive to produce and are therefore particularly suitable for coatings on low-cost mass-produced products. Above all because, apart from the production of the cover layer 3, in principle only one Mo evaporation source needs to be provided for the production of the other parts of the coating system 2 in addition to the process gas nitrogen, which means a minimal effort with regard to the equipment of the coating chamber and greatly simplifies the coating process itself.

All substrates 1 according to the invention of the embodiments according to FIG. 1a to 1d are provided with a multilayer coating system 2 in the form of a surface coating with an outer cover layer 3 comprising an amorphous carbon. Between the substrate 1 and the cover layer 3, at least exactly one first MoₐNₓ support layer 4 is provided in each case, which, referred to a Mo content a, has a nitrogen content x which is in the range of 25 at %≤x≤55 at %, with x+a=100 at %.

At this point, it should again be indicated that when, for the sake of simplicity, in the context of the present application, reference is made to a “MoN layer” or simply to “MoN”, this means a chemical composition or a layer comprising at least Mo and N of any composition relating to Mo and N. Thus, within the meaning of this application, MoN or a MoN layer may be, for example, in particular a first MoₐNₓ support layer 4 or a second Mo_{b}N_{y} support layer 5 or any other layer or composition of the MoN type. Thus, MoN is to be understood as a kind of generic term for the molybdenum-nitrogen layers or molybdenum-nitrogen compositions defined in this application.

In the simple embodiments of FIG. 1a to FIG. 1d, the MoN layers shown are each first MoₐNₓ support layers 4.

The outer cover layer 3 comprising the amorphous carbon can be any type of an amorphous carbon layer. For example, a very simple amorphous carbon layer of the a-C type, or an amorphous carbon layer of the a-C:X type doped with an element X, or a tetrahedral amorphous carbon layer of the ta-C:X type doped with an element X, an amorphous carbon layer of the a-C:Me type doped with a metal, a tetrahedral amorphous carbon layer of the ta-C:Me type doped with a metal, or an amorphous carbon layer of the a-C:H:Me type doped with a metal and hydrogen, or, e.g. a tetrahedral amorphous carbon layer of the ta-C:H:Me type doped with a metal and hydrogen. The cover layer 3 could also be designed as a multilayer coating formed from one or more aforementioned amorphous carbon layer types, or be designed in the form of one or more gradient layers or be designed in some other way as an amorphous carbon layer, as indicated in the context of the description and claims of this application.

The thicknesses or thickness ratios and hardnesses or hardness ratios of the individual layers of the coating system 2, as represented schematically in the figures of the present application, may assume any suitable values as explained in the present description and the claims. Thus, in particular, the layer thicknesses or layer thickness ratios of the individual layers of the shown coating systems 2 or of the substrate 1 represented in all figures are, of course, to be understood as purely schematic and do not reflect actual thicknesses or actual layer thickness ratios.

The substrate can be in particular a component of a component subject to wear and/or friction, especially a component of a motor vehicle or of an internal combustion engine, in particular a piston, or a piston ring, a valve, a valve disk, or another component of an internal combustion engine or also a tool, such as a cutting tool, a forming tool, a machining tool, or another tool subject to wear and/or friction, or any other substrate which can advantageously be provided with a coating of the present invention.

Thus, the previously made comments on the outer cover layer 3 of amorphous carbon, on the substrate 1 and on the thicknesses and thickness ratios, as well as the hardnesses and hardness ratios of the layers of the coating system 2 also apply to all other special coating systems of the invention discussed below and therefore, need not to be explicitly repeated again in the discussion of the following figures FIG. 2a to FIG. 2e, FIG. 3a to FIG. 3 c, or FIG. 4a and FIG. 4b, as well as for the coating systems in FIG. 5a and FIG. 5b. Therefore, in the following, in the discussion of further coating systems of the invention, for the sake of simplicity, only a cover layer 3 or a substrate 4 will be referred to in each case, without having to specify them in any further detail.

Back to the specific embodiments according to FIG. 1a to FIG. 1d, the simplest layer type of a coating system 2 of the present invention is represented in an exemplary manner on the basis of FIG. 1a, which coating system is characterized by the fact that exactly one first MoₐNₓ support layer 4, and no further layer, is provided between the cover layer 3 and the substrate 1. This type of layer, which can be produced simply and inexpensively, is particularly well suited if there are no particularly high requirements for the adhesion of the first MoₐNₓ support layer 4 on the substrate or of the cover layer 3 on first MoₐNₓ support layer 4 in the application of the coated substrate 1.

In the coating system 2 of FIG. 1b, a Mo adhesive layer is additionally provided between the substrate 1 and the first MoₐNₓ support layer 4 in comparison with that of FIG. 1a. In doing so, in particular the adhesion of the first MoₐNₓ support layer 4 on the substrate is improved.

In the further variant according to FIG. 1c, the adhesive layer 6 of Mo is provided between the cover layer 3 and the first MoₐNₓ support layer 4, so that primarily the adhesion of the cover layer to the underlying coating system 2 with substrate 1 is improved.

Then, the coating system according to FIG. 1d combines the advantages of the embodiments according to FIG. 1b and FIG. 1c by providing an adhesive layer 6 of molybdenum both between the cover layer 3 and the first MoₐNₓ support layer 4, and between the first MoₐNₓ support layer 4 and the substrate 1, so that a very good adhesion of all layers involved to each other as well as a good adhesion of the first MoₐNₓ support layer 4 on the substrate 1 is achieved.

Systemic further developments of the simple embodiments according to FIG. 1a to FIG. 1d are schematically represented on the basis of FIG. 2a to FIG. 2b. In these embodiments, the adhesive layers 6 according to FIG. 1a to FIG. 1b are partially or completely replaced by adhesive layers of another metal, in the present embodiments of FIG. 2a to FIG. 2b exemplarily by adhesive layers of Cr. This makes the production of the coating system 2 somewhat more complex, since the coating chamber must additionally be equipped with at least one metal evaporation source, in this case a Cr evaporation source, and makes the process control in the coating process somewhat more complex. However, the layer systems can be adapted even more flexibly to special requirements to which the substrate is subjected in the operating state by the substitutional, additional, or alternative use of adhesion layers of metal such as Cr instead of adhesion layers of Mo only.

In the embodiment according to FIG. 2a, in comparison to that of FIG. 1b, the adhesive layer 6 of Mo between the first MoₐNₓ support layer 4 and the substrate 1 is replaced by an adhesive layer 6 of Cr, while in the embodiment of FIG. 2b, the adhesive layer 6 between the cover layer 3 and the first MoₐNₓ support layer 4 is replaced by an adhesive layer 6 of Cr. In the embodiment according to FIG. 2c, in comparison to that of FIG. 1d, even both adhesive layers 6 are of Cr, both the one between the first MoₐNₓ support layer 4 and the substrate 1, and the one between the cover layer 3 and the first MoₐNₓ support layer 4 are replaced by an adhesive layer 6 of Cr.

In FIG. 2d and FIG. 2e, two types of adhesive layers 6 are provided in each case, namely an adhesive layer 6 of Mo and an adhesive layer 6 of Cr. In FIG. 2d, an adhesive layer 6 of Cr is provided between the cover layer 3 and the first MoₐNₓ support layer 4, and an adhesive layer 6 of Mo is provided between the first MoₐNₓ support layer 4 and the substrate 1, while in the embodiment of FIG. 2e, an adhesive layer 6 of Mo is provided between the cover layer 3 and the first MoₐNₓ support layer 4, and an adhesive layer 6 of Cr is provided between the first MoₐNₓ support layer 4 and the substrate 1. Thus, the two embodiments according to FIG. 2d and FIG. 2e are two further advantageous modifications of FIG. 1d, between which the person skilled in the art can select in practice depending on the requirements by the specific application of the coated substrate 1.

On the basis of FIG. 3a to FIG. 3c, further developments of the coating systems 2 according to the special embodiments previously described above are schematically sketched, which comprise an intermediate layer 7 between the cover layer 3 and the substrate 1 in addition to the at least one first MoₐNₓ support layer 4 and in addition to the at least one adhesive layer 6.

As already explained in more detail above, an intermediate layer 7, not only in the case of, but in particular in the case of the use of soft steels for the substrate 1, can additionally be provided advantageously in the coating system 2, wherein an additional intermediate layer 7 can be provided particularly preferably under a MoN support layer, i.e. e.g. under a first MoₐNₓ support layer 4 or a second Mo_{b}N_{y} support layer 5, very particularly preferably in the direction towards the substrate 1.

Due to the integration of one or more additional intermediate layers 7 between the cover layer 3 and the substrate 1, inter alia, layer properties such as the stability, hardness, above all also the temperature resistance, the adaptation to impact loads or also the ductility etc. can be individually adapted or further improved in a coating system 2 according to the invention depending on the application and substrate.

In the embodiments according to FIG. 3a to FIG. 3c, only one and in addition a relatively simply constructed intermediate layer 7 of the composition CrN is provided in each case. The Young's modulus and the hardness of the partial layers or partial areas of the coating system preferably increase in the direction towards the cover layer. In particular, the Young's modulus and the hardness of the intermediate layer 7 are particularly preferably smaller than the Young's modulus and the hardness of the first MoₐNₓ support layer 4 and/or the second Mo_{b}N_{y} support layer 5 and/or the cover layer 3. This relationship will be illuminated in more detail below on the basis of FIG. 6. In practice, the person skilled in the art can select from a large number of different types of intermediate layers 7 for the production of a coating system 2 according to the invention, such as from intermediate layers comprising single-phase metal nitrides and/or metal carbides as well as metal carbonitrides and/or phase mixtures of metal nitrides, metal carbides and metal carbonitrides, wherein the intermediate layer 7 can in particular be a single-phase Cr₂N or a single-phase CrN layer, as in the embodiments of FIG. 3a to FIG. 3c, or can comprise a phase mixture of CrN and Cr₂N and can otherwise have special properties and embodiments as already described in detail elsewhere in the context of this application.

In FIG. 3a, an additional intermediate layer 7 of CrN is deposited between the adhesive layer 6 of Cr provided on the substrate 1 and the first MoₐNₓ support layer 4 provided under the cover layer 3. Thus, the embodiment of FIG. 3a can be understood as a development and further improvement of the embodiment according to FIG. 2a.

In FIG. 3b, an additional intermediate layer 7 of CrN is also deposited between the adhesive layer 6 of Cr provided on the substrate 1 and under the first MoₐNₓ support layer 4, wherein in this embodiment, in comparison to FIG. 3a, an adhesive layer 6 is additionally provided between the cover layer 3 and the first MoₐNₓ support layer 4. Thus, the embodiment of FIG. 3b can be understood as a development and further improvement of the embodiment according to FIG. 3a or also as a further improvement of the embodiment according to FIG. 2c.

The embodiment according to FIG. 3c, on the other hand, can be understood as a development of the embodiment of FIG. 2e. In the embodiment of FIG. 3c, in comparison to FIG. 2e, an intermediate layer of CrN is additionally deposited between the adhesive layer 6 of Cr provided on the substrate 1 and the first MoₐNₓ support layer 4.

Although it would be possible to present a large number of further embodiments of coating systems 2 according to the invention on the basis of specific embodiments, for the sake of clarity and the required brevity of the presentation, only one important further type of coating systems 2 according to the invention will be briefly presented in detail on the basis of FIG. 4a and FIG. 4b.

In the case of the coating systems 2 according to the present invention represented schematically on the basis of FIG. 4a and FIG. 4b, these are coating systems which additionally comprise multilayer coatings 71.

In the context of this application, a multilayer coating 71 is to be understood as such a sublayer of the coating system 2 which comprises a plurality of individual different partial layers 4, 5, 6, 7, the individual thicknesses of which are each relatively or rather small in comparison to the thickness of the entire coating system 2 or in comparison to the thickness of most other partial layers of the coating system 2 or in comparison to the thickness of the entire multilayer coating 71.

In the embodiment of FIG. 4a, as a development of the simple embodiment according to FIG. 2c, instead of a simple first MoₐNₓ support layer 4, a multilayer coating 71 is provided between the two adhesive layers 6 of Cr, which comprises in alternating sequence a plurality of individual thin layers of CrN intermediate layers and the first MoₐNₓ support layers 4.

In the embodiment according to FIG. 4b, in comparison to FIG. 4a, a further second multilayer coating 71 is additionally provided on the adhesive layer 6 of Cr deposited on the substrate 1, which comprises in alternating sequence a plurality of individual thin layer of a first CrN1 having a first composition of Cr and nitrogen and further comprises a plurality of individual thin layer layers of a second CrN2 having a second composition of Cr and nitrogen different from the first composition according to CrN1.

It is understood that the multilayer coating 71 according to the present invention can also comprise more than two different types of partial layers, or a coating system 2 according to the invention can also comprise more than two identical or different multilayer coatings 71, which can be provided at different positions in the coating system 2.

In addition, it is also possible that a multilayer coating 71 is partially or completely designed as a gradient layer in which the chemical composition changes more or less continuously in a characteristic manner with respect to a coating direction.

Finally, on the basis of FIGS. 5a and 5b, two further embodiments of coating systems 2 according to the invention are discussed schematically, which are provided with at least a first and a second support layer under the cover layer 3. Here, the nitrogen content x of the first MoₐNₓ support layer 4 is in the range of 30 at %≤x≤53 at % and is particularly advantageous at about 50 at %. If in a very specific embodiment, in which the first MoₐNₓ support layer 4 is e.g., a gradient layer, the hardness of the first MoₐNₓ support layer 4 may preferably increase by an increasing nitrogen content in the direction towards the cover layer 3. In addition, in the coating system 2 of FIG. 5a and FIG. 5b, at least a second Mo_{b}N_{y} support layer 5 is provided between the first MoₐNₓ support layer 4 and the substrate 1, wherein, referred to a Mo content b of the second Mo_{b}N_{y} support layer, a nitrogen content y is in the range of 35 at %≤y≤45 at %, with y+b=100 at %, and preferably at 40 at %. This means that the hardness H of the second Mo_{b}N_{y} support layer 5 is in particular smaller than that of the first MoₐNₓ support layer 4, so that the hardness H of the coating system preferably increases in the direction towards the cover layer 3. The same applies here in an analogous manner: if, in a very specific embodiment, the second Mo_{b}N_{y} support layer 5 is, for example, a gradient layer, the hardness H of the second Mo_{b}N_{y} support layer 5 can preferably increase in the direction towards the cover layer 3 due to an increasing nitrogen content, i.e., decrease in the direction towards the substrate 1.

In the specific embodiment example of FIG. 5b, an adhesive layer 6 of Cr is additionally provided to improve the adhesion between the substrate 1 and the second Mo_{b}N_{y} support layer 5. And in addition, a further adhesive layer 6 of Mo+Mo₂N is provided in each case between the first MoₐNₓ support layer 4 and the second Mo_{b}N_{y} support layer 5, and between the first MoₐNₓ support layer 4 and the cover layer 3, wherein they are preferably designed as Mo layer with a Mo₂N minor phase in each case.

Finally, on the basis of FIG. 6, a preferred course of the hardness H and the Young's modulus E for a special coating system of the invention with a coating system according to the invention deposited on a substrate 1 of steel will be discussed by way of example. The special coating system 2 of FIG. 6 comprises an adhesive layer 6 arranged on the substrate 1, a subsequent intermediate layer 7 and a MoN support layer system 4, 5 arranged on a further adhesive layer 6, which lies immediately below the cover layer 3. The hardness in GPa is plotted on the left at the ordinate of the diagram in FIG. 6, the Young's modulus in GPa on the right and the thickness D of the coating system in nm on the abscissa.

It can be clearly recognized that here the hardness of the substrate 1 of the coating system 2 with the substrate 1 becomes increasingly larger in the direction towards the cover layer 3. The same applies to the Young's modulus, which also becomes increasingly larger away from the substrate 1 in the direction towards the cover layer 3. In particular, it can be clearly recognized that the intermediate layer 7 has a smaller hardness H and a smaller Young's modulus E than the MoN support system 4, 5 comprising the first MoₐNₓ support layer 4 and/or the second Mo_{b}N_{y} support layer 5, and also the hardness of the MoN support system 4, 5 comprising the first MoₐNₓ support layer 4 and/or the second Mo_{b}N_{y} support layer increases towards the cover layer.

It is understood that for all the embodiments previously described in the general description and in the figures, further embodiments are also conceivable in practice, which may comprise further additional layer types according to the invention between the cover layer 3 and the substrate 1. Thus, depending on the application and requirements of the coated substrate 1, additional layers, such as one or more additional first MoₐNₓ support layers 4, additional second Mo_{b}N_{y}support layers 5, additional intermediate layers 7, or even additional adhesive layers 6 can be provided at a suitable location in the coating system 2, which, for reasons of clarity, are not necessarily represented explicitly in the figures of the present application.

Which exact layer composition and architecture of the coating system 2 is to be selected in the specific application is left to the person skilled in the art who knows how to select the most suitable coating system 2 based on his experience or by using relevant criteria and tests known per se.

1. A substrate having a multilayer coating system in the form of a surface coating, which has an outer cover layer comprising amorphous carbon, characterized in that at least a first MoₐNₓ support layer is provided between the substrate and the cover layer, which support layer has a nitrogen content x, referred to an Mo content a, which is in the range of 25 at %≤x≤55 at %, with x+a=100 at %.

2. The substrate according to claim 1, wherein the nitrogen content x of the first MoₐNₓ support layer is in the range of 30 at %≤x≤53 at %, preferably at about 50 at %.

3. The substrate according to claim 1, wherein the coating system comprises at least a second Mo_{b}N_{y} support layer between the substrate and the first MoₐNₓ support layer and/or between the first MoₐNₓ support layer and the outer cover layer, wherein, referred to a Mo content b of the second Mo_{b}N_{y} support layer, a nitrogen content y is in the range from 35 at %≤y≤45 at %, with y+b=100 at %, preferably at 40 at %.

4. The substrate according to claim 1, wherein a plurality of respectively identical or different first MoₐNᵣ support layers is provided between the substrate and the outer cover layer of amorphous carbon and/or wherein a plurality of respectively identical or different second Mo_{b}N_{y} support layers is provided between the substrate and the outer cover layer of amorphous carbon and/or wherein the first MoₐNₓ support layer and/or the second Mo_{b}N_{y} support layer contains a proportion of metallic Mo, wherein a phase mixture of Mo and Mo₂N in the first MoNₓ support layer and a phase mixture of Mo and Mo₂N in the second Mo_{b}N_{y} support layer, respectively, is adjusted by adjusting a nitrogen content x and y, respectively, between 5 at % and 20 at %, with x+a=100 at % and y+b=100 at % and/or wherein the first MoₐNₓ support layer and/or the second Mo_{b}N_{y} support layer are composed of pure Mo₂N phases and their phase mixtures β-Mo₂N and γ-Mo₂N, and/or of Mo₂N/MoN phase mixtures and/or of pure MoN phases, in particular cubic MoN phases and/or hexagonal δ-MoN phases or phase mixtures, the γ-Mo₂N and the pure hexagonal phase of δ-MoN being particularly preferred.

5. The substrate according to claim 1, wherein the first MoₐNₓ support layer and/or the second Mo_{b}N_{y} support layer additionally comprises one or more elements from the group consisting of [Ag, Cr, Ti, Cu, Al, Si, B, O, C] and/or an element from the 4th, 5th or 6th group of the periodic table of the elements, and wherein the first MoₐNₓ support layer and/or the second Mo_{b}N_{y} support layer comprises at least a layer of the composition (MoₓM_{z})_{c}(NᵤCᵥO_{w})_{d}, acting as a support layer, wherein M comprises at least one of the elements of the 4th to 6th group of the periodic table, and/or one of the elements Si, B, Al, Cu, Ag, with x+z+u+v+w=100 at %, and c/d=3, wherein 25 at %≤x≤55 at % and 0≤z≤20 at %, 0≤v≤5 at % and 0≤w≤5 at %.

6. The substrate according to claim 1, wherein the coating system additionally comprises an adhesive layer provided on a surface of the substrate and/or on a surface of the first MoₐNₓ support layer and/or on a surface of the second Mo_{b}N_{y} support layer, which adhesive layer is alloyed in particular with one or more elements from the group consisting of [C, N, O] and/or wherein the adhesive layer comprises, except for impurities, one or more elements of the 4th, 5th or 6th group of the periodic table of the elements, in particular also comprising one of the elements Cr, Ti, Cu, Al, Mo.

7. The substrate according to claim 1, wherein the coating system additionally comprises an intermediate layer under the first Mo_{z}Nₓ support layer and/or under the second Mo_{b}N_{y} support layer, in particular single-phase metal nitrides, metal carbides as well as metal carbonitrides and/or phase mixtures of metal nitrides, metal carbides and metal carbonitrides, wherein the intermediate layer comprises in particular a single-phase Cr₂N or CrN layer or a phase mixture of CrN and Cr₂N and/or wherein the first MoₐNₓ support layer and/or the second Mo_{b}N_{y} support layer and/or the intermediate layer is a gradient layer referred to the chemical composition.

8. The substrate according to claim 1, wherein a thickness d of the first MoₐNₓ support layer and/or of the second Mo_{b}N_{y} support layer and/or of the intermediate layer is in the range of 0.05 μm≤d≤50 μm, preferably in the range of 0.03 μm≤d≤30 μm, especially in the range of 0.2 μm≤d≤μm, or in the range of 0.3 μm≤d≤10 μm.

9. The substrate according to claim 1, wherein the outer cover layer comprising the amorphous carbon is an amorphous carbon layer of the a-C type, an amorphous carbon layer of the a-C:X type doped with an element X, a tetrahedral amorphous carbon layer of the ta-C:X type doped with an element X, an amorphous carbon layer of the a-C:Me type doped with a metal, a tetrahedral amorphous carbon layer of the ta-C:Me type doped with a metal, or an amorphous carbon layer of the a-C:H:Me type doped with a metal and hydrogen or a tetrahedral amorphous carbon layer of the ta-C:H:Me type doped with a metal and hydrogen and/or wherein X is preferably an element from the group of elements consisting of [F, Cl, B, N, O, Si] and/or wherein Me comprises one or more elements of the 4th, 5th or 6th group of the periodic table of the elements and preferably comprises one of the elements Al, Mo, Cr, Ti, W, Al, Cu.

10. The substrate according to claim 9, wherein the cover layer is of two or more layers each comprising an amorphous carbon layer of the a-C type, or of the a-C:X type, or of the ta-C:X type, or of the a-C:Me type, or of the ta-C:Me type, or of the a-C:H:Me type, or of the ta-C:H:Me type and/or wherein the cover layer and/or a layer comprising a gradient layer is an amorphous carbon layer of the a-C type, or of the a-C:X type, or of the ta-C:X type, or of the a-C:ME type, or of the ta-C:Me type, or of the a-C:H:Me type, or of the ta-C:H:Me type and/or wherein two different layers of the cover layer have a different sp³/sp² ratio and/or wherein in a gradient layer a sp³/sp² ratio varies over a thickness of the gradient layer.

11. The substrate according to claim 10, wherein a thickness Dd of the cover layer and/or of a layer of the cover layer is in the range of 0.05 μm≤Dd≤50 μm, preferably in the range of 0.05 μm≤Dd≤30 μm, especially in the range of 0.1 μm≤Dd≤20 μm, or in the range of 0.5 μm≤Dd≤10 μm, preferably in the range of 1 μm≤Dd≤5 μm, particularly preferably at about 2 μm and/or wherein a hardness Hd of the cover layer is in a range of 8 GPa≤Hd≤80 GPa, especially in the range of 10 GPa≤Hd≤70 GPa, or in the range of 25 GPa≤Hd≤60 GPa, particularly preferably at about 50 GPa.

12. The substrate according to claim 1, wherein a total thickness Gd of the coating system is in the range of 0.05 μm≤Gd≤100 μm, preferably in the range of 0.5 μm≤Gd≤50 μm, especially in the range of 1 μm≤Gd≤10 μm, particularly preferably at about 4 μm and/or wherein a ratio of the thickness Dd of the cover layer to the total thickness of the Gd of the entire coating system is in the range of
1%≤(Dd/Gd)≤1000%, preferably in the range of
10%≤(Dd/Gd)≤500%, especially in the range of
20%≤(Dd/Gd)≤200% and particularly preferably in the range of
40%≤(Dd/Gd)≤120% and/or wherein a ratio of the hardness Hd of the cover layer (3) to the hardness Hs of the entire support layer is in a range between (Hd/Hs)=1:5 to (Hd/Hs)=4:1, preferably in the range between (Hd/Hs)=1:2 to (Hd/Hs)=3:1, in particular in the range of (Hd/Hs)=1:1.5 to (Hd/Hs)=2:1.

13. The substrate according to claim 1, wherein the substrate is in particular a component of a component subject to wear and/or friction, especially a component of a motor vehicle or of an internal combustion engine, in particular a piston, or a piston ring, a valve, a valve disk, or another component of an internal combustion engine or a tool, such as a cutting tool, a forming tool, a machining tool, or another tool subject to wear and/or friction.

14. A coating process for producing a coating system on a substrate according claim 1, wherein the coating process comprises a PVD process, a CVD process, a PA-CVD process, a sputtering process, preferably a HIPMS sputtering process, in particular a filtered or unfiltered are coating process, or a combination or hybrid process comprising at least one of the aforementioned coating processes, and/or wherein the coating of the entire coating system is deposited on the substrate by of the unfiltered or filtered arc evaporator.

15. The coating process according to claim 14, wherein the substrate is treated for cleaning of the substrate surface and/or a surface of the first MoₐNₓ support layer and/or a surface of the second Mo_{b}N_{y} support layer prior to coating by argon ions and/or hydrogen with an ion cleaning using an Arc Enhanced Glow Discharge AEGD technology, wherein preferably additionally an ion treatment is carried out for example with Cr ions or Mo ions.
